(19) United States
(12) Patent Application Publication
(10) Pub. No.: US 2009/0311629 A1
(43) Pub. Date: Dec. 17, 2009

(54) METHOD FOR MANUFACTURING ROLLER MOLD

(75) Inventors: Yung-Chun LEE, TAINAN CITY (TW); Cheng-Yu CHIU, TAOYUAN COUNTY (TW)

Correspondence Address: Chih Feng Yeh;BRIAN M. MCINNIS, 12th Floor, Ruttonjee House, 11 Duddell Street, Hong Kong, HK

(73) Assignee: NATIONAL CHENG KUNG UNIVERSITY, TAINAN CITY (TW)

(21) Appl. No.: 12/483,254

(22) Filed: Jun. 12, 2009

(30) Foreign Application Priority Data
Jun. 12, 2008 (TW) 97121936

(51) Int. Cl. G03F 7/20

(52) U.S. Cl. 430/320

(57) ABSTRACT

A method for manufacturing a roller mold is described, including the following steps. A body is provided, wherein the body is a cylinder. A photoresist layer is formed to completely cover a cambered surface of the body. A mold including a pattern structure including a convex portion and a concave portion is provided, and the convex portion and the concave portion are covered with a transferred pattern layer. The mold is pressed on the photoresist layer. The body is rolled to transfer the transferred pattern layer on the convex portion onto the photoresist layer. The mold is removed. An UV light exposure step is performed on an exposed portion of the photoresist layer to transfer a pattern of the transferred pattern layer to the photoresist layer. The exposed portion of the photoresist layer is removed to expose a portion of the cambered surface of the body. A structure layer is formed on the portion of the cambered surface and the transferred pattern layer. The photoresist layer, and the structure layer and the transferred pattern layer on the photoresist layer are removed.

### RELATED APPLICATIONS

This application claims priority to Taiwan Application Serial Number 97121936, filed Jun. 12, 2008, which is herein incorporated by reference.

### FIELD OF THE INVENTION

The present invention relates to a method for manufacturing an imprinting mold, and more particularly to a method for manufacturing a roller mold.

### BACKGROUND OF THE INVENTION

Currently, due to the optical diffraction limit, the size of the pattern feature, which the photolithography technique can define, is limited seriously. Therefore, the developing potential of a micro/nano-imprinting technology has attracted much attention, and has been regarded as one possible method that can surpass and replace the conventional micro/nano photolithography technology.

Currently, many micro/nano-imprinting techniques have been developed. However, the micro/nano-imprinting apparatus applying the commercial micro/nano-imprinting technique needs long imprinting time, so that the quantity of output per unit time is less, and the throughput is very low. In accordance with the aforementioned reasons, a micro/nano-rolling-imprinting technique has been developed to improve the poor throughput of the current micro/nano-imprinting technique. The micro/nano-rolling-imprinting technique can greatly increase the quantity of output per unit time, so that how to achieve the mass production of the nano/micro-rolling-imprinting technique has become the development focal point in the field of the micro/nano-imprinting technique.

In the micro/nano-rolling-imprinting technique, one critical technique is the fabrication of the roller mold, because the fabrication of the roller mold is difficult. The difficulty of fabricating the roller mold is in accurately defining a pattern structure on a sub-micrometer scale or even on a nanometer scale onto a cambered surface of the roller.

Therefore, a method for manufacturing a roller mold that can successfully and accurately define a pattern structure on a micro/nano scale to a cambered surface of the roller mold is needed.

### SUMMARY OF THE INVENTION

Therefore, one objective of the present invention is to provide a method for manufacturing a roller mold, which can successfully transfer and dispose a feature pattern structure on the micro/nano-scale onto a cambered surface of the roller mold.

Another objective of the present invention is to provide a method for manufacturing a roller mold, which can effectively simplify the process steps of the roller mold. Therefore, the reliability of the process of the roller mold and the yield of the roller mold can be enhanced, and the precision of the pattern structure of the roller mold can be greatly increased.

According to the aforementioned objectives, the present invention provides a method for manufacturing a roller mold including the following steps. A body is provided, wherein the body is a cylinder. A photoresist layer is formed to completely cover a cambered surface of the body. A mold is provided, wherein a surface of the mold includes a pattern structure including a convex portion and a concave portion, and the convex portion and the concave portion are covered with an anti-stick layer and a transferred pattern layer in sequence. The surface of the mold is pressed on the photoresist layer. The roller's body is rolled to transfer the transferred pattern layer on the convex portion onto the photoresist layer. The mold is removed. An UV light exposure step is performed on an exposed portion of the photoresist layer to transfer a pattern of the transferred pattern layer to the photoresist layer. The UV light exposed portion of the photoresist layer is removed to expose a portion of the cambered surface of the body. A structure layer is formed on the portion of the cambered surface and the transferred pattern layer. The photoresist layer, and the structure layer and the transferred pattern layer on the photoresist layer are removed

According to a preferred embodiment of the present invention, a thickness of the photoresist layer is preferably less than one micrometer.

According to the aforementioned objectives, the present invention further provides a method for manufacturing a roller mold including the following steps. A roller body is provided, wherein the body is a cylinder. A photoresist layer is formed to completely cover a cambered surface of the body. A mold is provided, wherein a surface of the mold includes a pattern structure including a convex portion and a concave portion, and the convex portion and the concave portion are covered with an anti-stick layer and a transferred pattern layer in sequence. The surface of the mold is pressed on the photoresist layer. The body is rolled to transfer the transferred pattern layer as a photo mask on the convex portion onto the photoresist layer. The mold is removed. An UV light exposure step is performed on an exposed portion of the photoresist layer to transfer a pattern of the transferred pattern layer to the photoresist layer. The exposed portion of the photoresist layer is removed to expose a portion of the cambered surface of the body. An etching step is performed on the exposed portion of the cambered surface to remove a portion of the body to form a plurality of concave portions in the cambered surface. The photoresist layer and the transferred pattern layer are removed.

According to a preferred embodiment of the present invention, the materials of the transferred pattern layer and the structure layer may be metal, organic materials or dielectric materials.

According to another preferred embodiment of the present invention, the step of forming the structure layer is performed by an electron beam evaporation method, a thermal evaporation method, a chemical vapor deposition method or a physical vapor deposition method.

### BRIEF DESCRIPTION OF THE DRAWINGS

The foregoing aspects and many of the attendant advantages of this invention are more readily appreciated as the same become better understood by reference to the following detailed description, when taken in conjunction with the accompanying drawings, wherein:

FIGS. 1A through 1F are schematic flow diagrams showing a process for manufacturing a roller mold in accordance with a preferred embodiment of the present invention; and

FIGS. 2A through 2F are schematic flow diagrams showing a process for manufacturing a roller mold in accordance with another preferred embodiment of the present invention.

### DETAILED DESCRIPTION OF THE PREFERRED EMBODIMENT

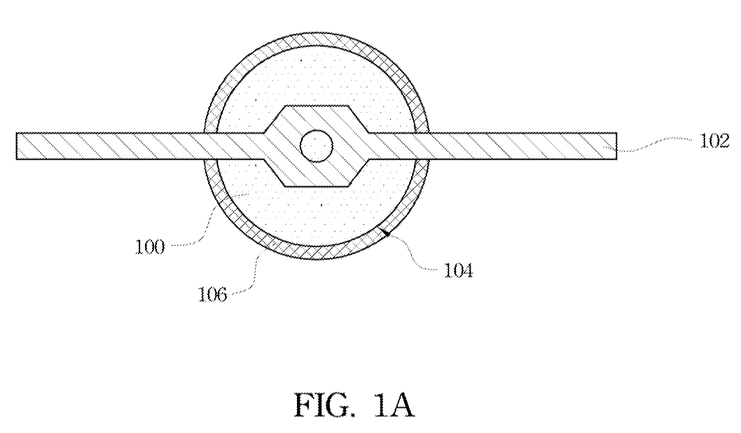

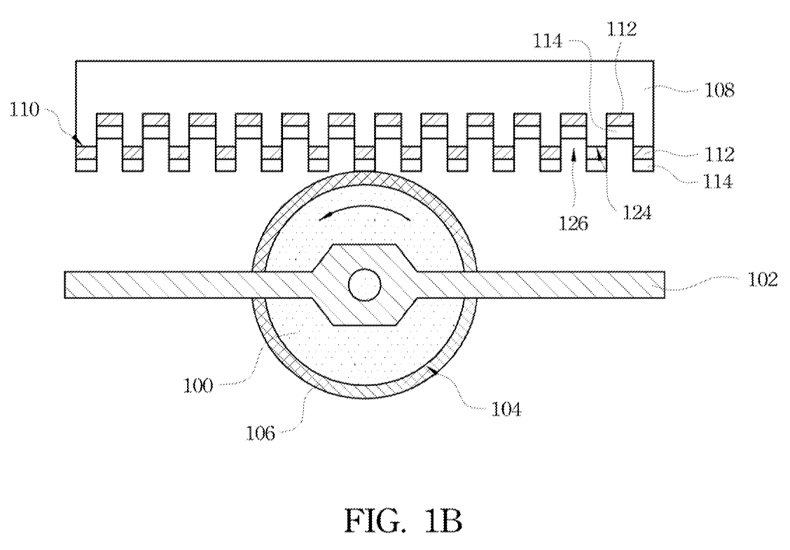

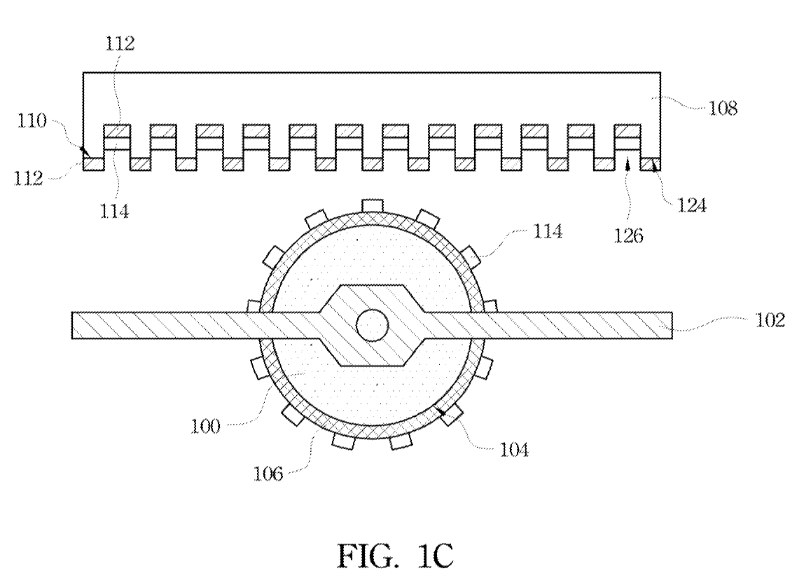

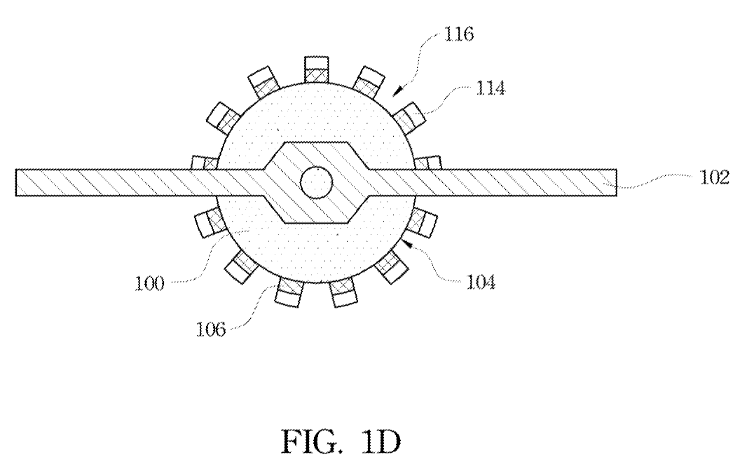

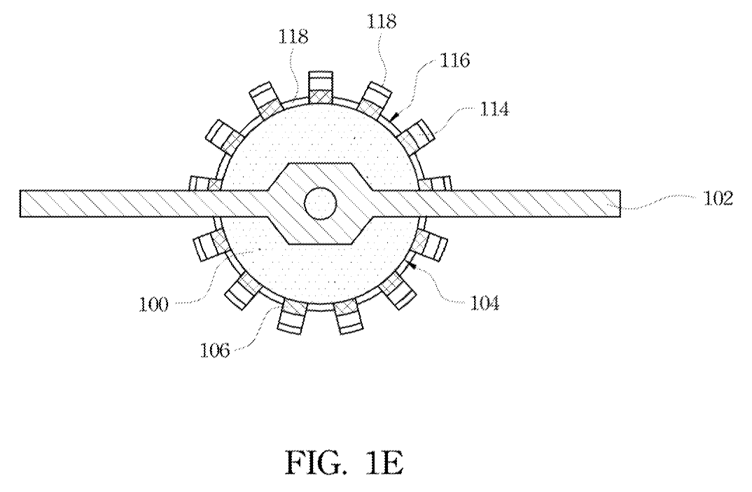

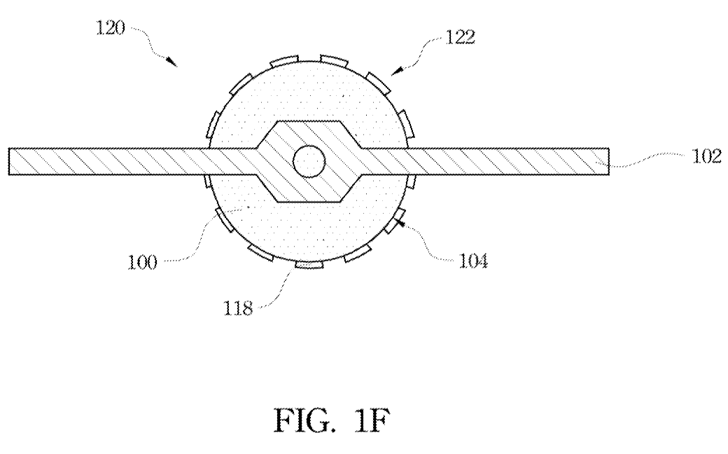

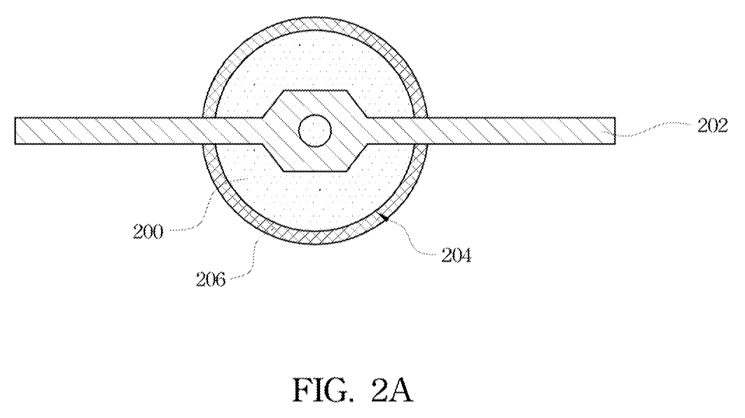

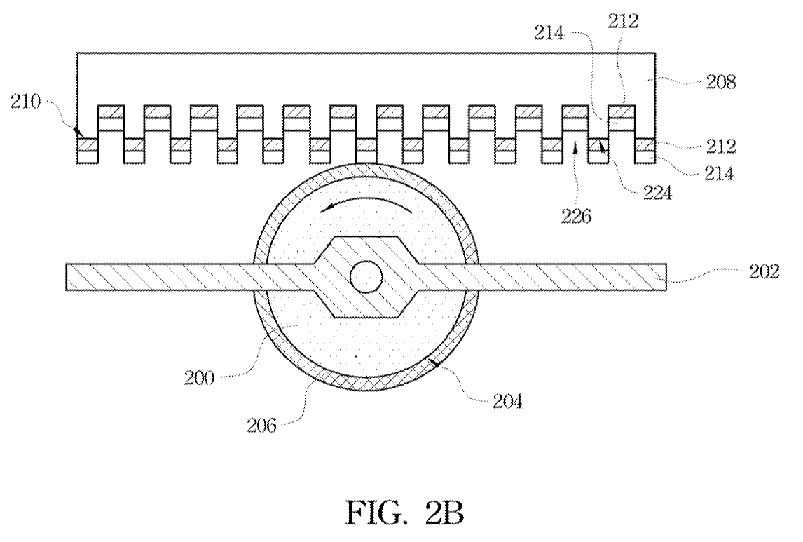

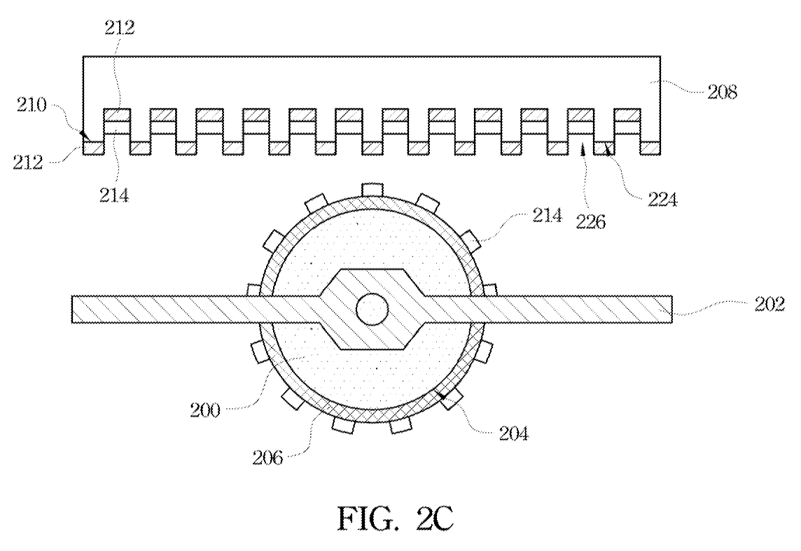

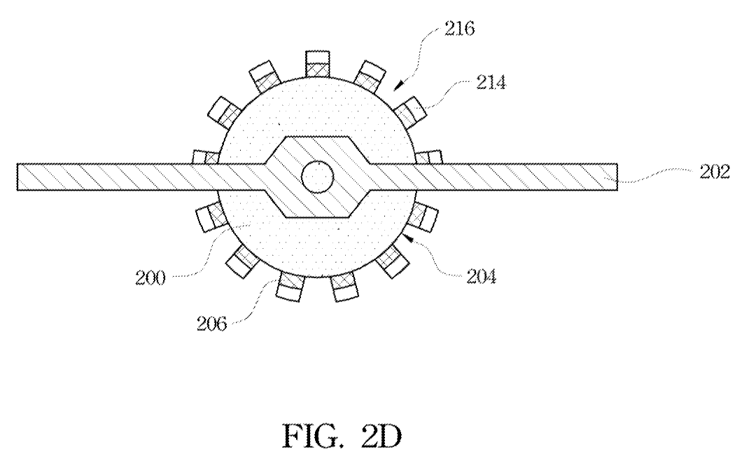

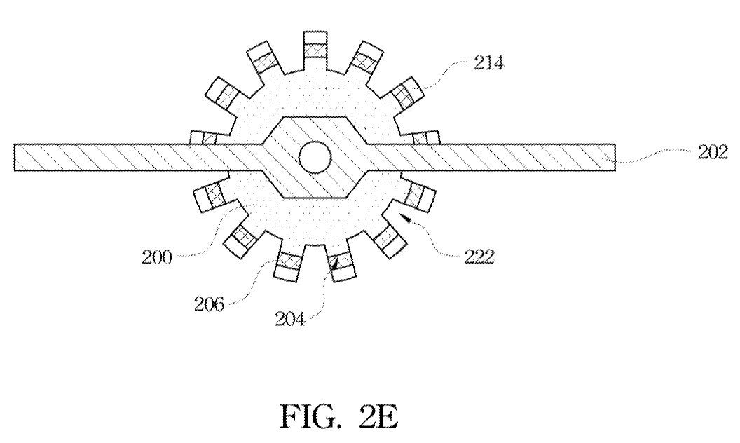

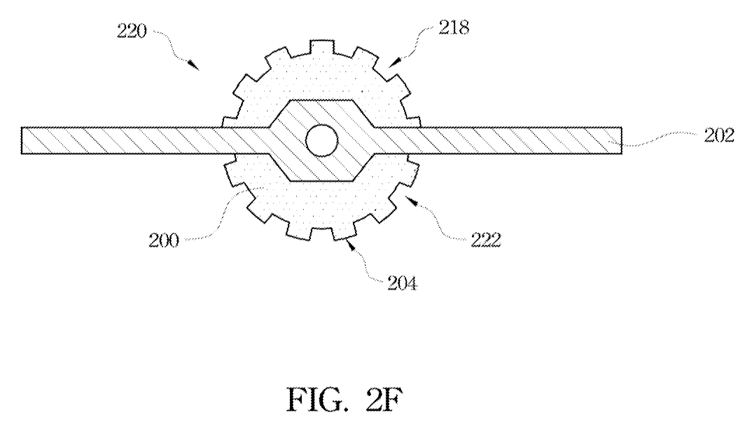

The present invention discloses a method for manufacturing a roller mold. In order to make the illustration of the present invention more explicit, the following description is stated with reference to FIGS. 1A through 2F.

Refer to FIGS. 1A through 1F. FIGS. 1A through 1F are schematic flow diagrams showing a process for manufacturing a roller mold in accordance with a preferred embodiment of the present invention. In one exemplary embodiment, in the fabrication of a roller mold, a body 100 is firstly provided. The body 100 may be horizontally mounted on a carrier 102 selectively, wherein the body 100 is a cylinder. The material of the body 100 may be, for example, glass, quartz, or metal. A polishing treatment may be performed on a cambered surface 104 of the body 100 to make the body 100 have a smooth cambered surface 104. Then, a photoresist layer 106 is formed on the cambered surface 104 of the body 100 by a spray method with an airbrush for example. The photoresist layer 106 preferably completely covers the cambered surface 104 of the body 100, such as shown in FIG. 1A. When the photoresist layer 106 is sprayed on the cambered surface 104 of the body 100, the photoresist layer 106 may be sprayed toward the cambered surface 104 of the body 100 while the body 100 is rotated with the support of the carrier 102. The photoresist layer 106 may be composed of a positive-tone photoresist or a negative-tone photoresist. In the present exemplary embodiment, the photoresist layer 106 is composed of a positive-tone photoresist. The photoresist layer 106 is preferably thinner to facilitate the subsequent treatment. In one embodiment, the thickness of the photoresist layer 106 is less than one micrometer.

Next, a mold 108 to be imprinted is provided. The mold 108 may be a flat mold, and a surface 110 of the mold 108 is preset with a desired pattern structure. In some embodiments, the mold for imprinting may also be a roller mold with a cambered surface. In other embodiments, the mold 108 may be a flexible mold, for example, ethylene tetrafluoroethylene produced by the DuPont Company. In further another embodiment, the mold 108 may be a rigid mold, and the material of the rigid mold may be silicon, quartz, glass or metal. In one embodiment, an anti-stick layer 112 may be selectively coated on the surface 110 of the mold 108. The anti-stick layer 112 may only be disposed on convex portions 124 and bottoms of concave portions 126 of the pattern structure on the surface 110 of the mold 108 substantially, such as shown in FIG. 1B.

In another embodiment, when the material of the mold 108 has an anti-stick property, such as a fluorine-containing polymer-based material with an anti-stick effect, the anti-stick layer 112 may not be additionally formed on the surface of the mold 108. The fluorine-containing polymer-based material with the anti-stick effect is, for example, ethylene tetrafluoroethylene produced by the DuPont Company. The ethylene tetrafluoroethylene produced by the DuPont Company is a flexible and having anti-stick property material.

A transferred pattern layer 114 is formed on the anti-stick layer 112 by, for example, a thermal evaporation method or an electron beam evaporation method, or a chemical vapor deposition method or a physical vapor deposition method cooperating with a typical pattern definition technique. The material of the transferred pattern layer 114 may be metal, an organic material, a dielectric material or oxide material, such as silicon dioxide. With the application of the anti-stick layer 112, the transferred pattern layer 114 can be successfully separated from the surface 110 of the mold 108. In one embodiment, the transferred pattern layer 114 includes pattern features on the sub-micrometer scale or the nanometer scale. Then, such as shown in FIG. 1B, the mold 108 is pressed in the photoresist layer 106 on the cambered surface 104 of the body 100 to make the transferred pattern layer 114 on the convex portions 124 of the surface 110 of the mold 108 contact with and be pressed on the photoresist layer 106. Then, a pressure is applied to the mold 108, and the body 100 is rotated simultaneously, to correspondingly press the transferred pattern layer 114 on the convex portions 124 of the surface 110 of the mold 108 and the photoresist layer 106 on the cambered surface 104 of the body 100 progressively, so as to transfer the transferred pattern layer 114 on the convex portions 124 of the surface 110 of the mold 108 from the surface 110 of the mold 108 onto the photoresist layer 106. At present, the surface 110 of the mold 108 is coated with the anti-stick layer 112, and the photoresist layer 106 is still in a liquid state and keeps viscous, so that the transferred pattern layer 114 on the convex portions 124 of the surface 110 of the mold 108 can be successfully separated from the mold 108 and transferred onto the photoresist layer 106.

Then, such as shown in FIG. 1C, the mold 108 is removed to separate the mold 108 from the body 100. At present, the transferred pattern layer 114 on the convex portions 124 of the surface 110 of the mold 108 has been completely adhered to the photoresist layer 106. The transferred pattern layer 114 is only disposed on a portion of the photoresist layer 106 and exposes the other portion of the photoresist layer 106. In some embodiments, before the subsequent UV light exposure step is performed, a baking treatment may be selectively performed on the photoresist layer 106 to solidify the liquid photoresist layer 106. Next, an UV light exposure step is performed on the exposed portion of the photoresist layer 106 by using the transferred pattern layer 114 as the photo mask to transfer the pattern of the transferred pattern layer 114 onto the photoresist layer 106. In one embodiment, in the UV light exposure step, the exposed portion of the photoresist layer 106 may be illuminated by deep ultraviolet (UV) light. Such as shown in FIG. 1D, a development step is performed after the exposure procedure. Because the photoresist layer 106 is composed of a positive-tone photoresist, the exposed portion of the photoresist layer 106 can be removed by the developer. After the exposed portion of the photoresist layer 106 is removed, a portion of the cambered surface 104 of the body 100, such as an exposed surface 116 shown in FIG. 1D, can be exposed.

Next, such as shown in FIG. 1E, a structure layer 118 is formed on the exposed surface 116 of the cambered surface 104 of the body 100 and the transferred pattern layer 114 by, for example, an electron beam evaporation method, a thermal evaporation method, a chemical vapor deposition method or a physical vapor deposition method. The material of the structure layer 118 may be metal, an organic material or a dielectric material. Then, the remaining photoresist layer 106 on the body 100 and the transferred pattern layer 114 and the structure layer 118 on the photoresist layer 106 are removed by, for example, a lift-off method, so as to expose the other portion of the cambered surface 104 of the body 100 and form an imprinting pattern 122 composed of the structure layer 118 and complementary to the pattern of the transferred pattern layer 114, to complete the fabrication of a roller mold 120, such as shown in FIG. 1F.

Refer to FIGS. 2A through 2F. FIGS. 2A through 2F are schematic flow diagrams showing a process for manufacturing a roller mold in accordance with another preferred embodiment of the present invention. In one exemplary embodiment, a cylinder body 200 is firstly provided, and the body 200 is horizontally mounted on a carrier 202 selectively. The material of the body 200 may be, for example, glass, quartz, or metal. A polishing treatment may be performed on a cambered surface 204 of the body 200 to smooth the cambered surface 204 of the body 200. Then, a photoresist layer 206 is formed on the cambered surface 204 of the body 200 by a spray method or an immersion method for example. The photoresist layer 206 preferably completely covers the cambered surface 204 of the body 200, such as shown in FIG. 2A. When the photoresist layer 206 is sprayed, the thin photoresist layer 206 may be sprayed toward the cambered surface 204 of the body 200 while the body 200 is rotated with the support of the carrier 202. When the photoresist layer 206 is formed by the immersion method, the body 200 is entirely immersed in a photoresist and then is taken out, and the thin photoresist layer 206 is finally formed on the cambered surface 204 of the body 200. The photoresist layer 206 may be composed of a positive-tone photoresist or a negative-tone photoresist. In the present exemplary embodiment, the photoresist layer 206 is composed of a positive-tone photoresist. In one preferred embodiment, the thickness of the photoresist layer 206 is less than one micrometer.

Next, a mold 208 to be imprinted is provided. The mold 208 may be a flat mold, and a surface 210 of the mold 208 is preset with a desired pattern structure. In some embodiments, the mold for imprinting may also be a roller mold with a cambered surface. In another embodiment, the mold 208 may be a flexible mold, and the material of the mold 208 may be ethylene tetrafluoroethylene produced by the DuPont Company. In further another embodiment, the mold 208 may be a rigid mold, and the material of the rigid mold may be silicon, quartz, glass or metal. In one embodiment, an anti-stick layer 212 may be selectively coated on the surface 210 of the mold 208. The anti-stick layer 212 may be only disposed on convex portions 224 and bottoms of concave portions 226 of the pattern structure on the surface 210 of the mold 208 substantially, such as shown in FIG. 2B.

In another embodiment, when the material of the mold 208 has an anti-stick property, such as a fluorine-containing polymer-based material with an anti-stick effect, the anti-stick layer 212 may not be additionally formed on the surface of the mold 208. The fluorine-containing polymer-based material with the anti-stick effect is, for example, ethylene tetrafluoroethylene produced by the DuPont Company.

A transferred pattern layer 214 is formed on the anti-stick layer 212 by, for example, a thermal evaporation method or an electron beam evaporation method, or a chemical vapor deposition method or a physical vapor deposition method cooperating with a typical pattern definition technique. The material of the transferred pattern layer 214 may be metal, an organic material, a dielectric material or oxide material, such as silicon dioxide. In one embodiment, the transferred pattern layer 214 includes pattern features on the sub-micrometer scale or the nanometer scale. Then, such as shown in FIG. 2B, the surface 210 of the mold 208 is pressed on the cambered surface 204 of the body 200 to make the transferred pattern layer 214 on the convex portions 224 of the surface 210 of the mold 208 contact with and be pressed on the photoresist layer 206. Subsequently, a pressure is applied to the mold 208, and the body 200 is rotated simultaneously, to correspondingly press the transferred pattern layer 214 on the convex portions 224 of the surface 210 of the mold 208 and the photoresist layer 206 on the cambered surface 204 of the body 200 progressively, so as to transfer the transferred pattern layer 214 as a photo mask on the convex portions 224 of the surface 210 of the mold 208 from the surface 210 of the mold 208 onto the photoresist layer 206. The surface 210 of the mold 208 is coated with the anti-stick layer 212, and the photoresist layer 206 is still in a liquid state and keeps viscous, so that the transferred pattern layer 214 on the convex portions 224 of the surface 210 of the mold 208 can be successfully separated from the mold 208 and transferred onto the photoresist layer 206.

After the transferring of the transferred pattern layer 214 is completed, such as shown in FIG. 2C, the mold 208 is removed to separate the mold 208 from the body 200. Presently, the transferred pattern layer 214 on the convex portions 224 of the surface 210 of the mold 208 has been completely adhered to the photoresist layer 206. Similarly, the transferred pattern layer 214 as a photo mask is only disposed on a portion of the photoresist layer 206 and exposes the other portion of the photoresist layer 206. In the other embodiments, before an UV light exposure step is performed, a baking treatment may be selectively performed on the photoresist layer 206 to solidify the liquid photoresist layer 206. Subsequently, an UV light exposure step is performed on the exposed portion of the photoresist layer 206 by, for example, using the deep ultraviolet light and using the transferred pattern layer 214 as the mask to transfer the pattern of the transferred pattern layer 214 onto the photoresist layer 206. After the exposure procedure is completed, a development step is performed by a developer to remove the exposed portion of the photoresist layer 206 to expose a portion of the cambered surface 204 of the body 200, such as an exposed surface 216 shown in FIG. 2D. Thus, the pattern definition of the photoresist layer 206 is completed.

Such as shown in FIG. 2E, after the pattern definition of the photoresist layer 206, by using the transferred pattern layer 214 as the etching mask and using, for example, a wet etching method, the exposed surface 216 of the cambered surface 204 of the body 200 is etched to remove a portion of the body 200, so as to form a plurality of concave portions 222 in the cambered surface 204 of the body 200 to further transfer the pattern of the photoresist layer 206 into the cambered surface 204 of the body 200. After the etching step, an imprinting pattern 218, which is substantially the same as the pattern of the transferred pattern layer 214, is now defined in the cambered surface 204 of the body 200. Then, the remaining photoresist layer 206 on the body 200 and the transferred pattern layer 214 on the photoresist layer 206 are removed by, for example, a lift-off method, so as to expose the other portion of the cambered surface 204 of the body 200 to complete the fabrication of a roller mold 220, such as shown in FIG. 2F.

According to the aforementioned embodiments of the present invention, one advantage of the present invention is that the method for manufacturing a roller mold can successfully transfer and dispose a feature pattern structure of micro/nano-scale onto a cambered surface of the roller mold, so that a rapid and large area imprinting of the nano-rolling-imprinting can be achieved.

According to the aforementioned embodiments of the present invention, another advantage of the present invention is that the method for manufacturing a roller mold can effectively simplify the process steps of the roller mold, so that the reliability of the process and the yield of the roller mold can be enhanced, and the precision of the pattern structure of the roller mold can be greatly increased.

As is understood by a person skilled in the art, the foregoing preferred embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A method for manufacturing a roller mold, including:
providing a body, wherein the body is a cylinder;
forming a photoresist layer completely covering a cambered surface of the body;
providing a mold, wherein a surface of the mold includes a pattern structure including a convex portion and a concave portion, and the convex portion and the concave portion are covered with a transferred pattern layer;
pressing the surface of the mold on the photoresist layer;
rolling the body to transfer the transferred pattern layer on the convex portion onto the photoresist layer;
removing the mold;
performing an UV light exposure step on an exposed portion of the photoresist layer to transfer a pattern of the transferred pattern layer to the photoresist layer;
removing the exposed portion of the photoresist layer to expose a portion of the cambered surface of the body;
forming a structure layer on the portion of the cambered surface and the transferred pattern layer; and
removing the photoresist layer, and the structure layer and the transferred pattern layer on the photoresist layer.

2. The method for manufacturing a roller mold according to claim 1, wherein a material of the body is glass, quartz, or metal.

3. The method for manufacturing a roller mold according to claim 1, wherein the step of forming the photoresist layer is performed by a spray method.

4. The method for manufacturing a roller mold according to claim 1, wherein the step of forming the photoresist layer is performed by an immersion method.

5. The method for manufacturing a roller mold according to claim 1, wherein the photoresist layer is composed of a positive-tone photoresist or a negative-tone photoresist.

6. The method for manufacturing a roller mold according to claim 1, wherein a thickness of the photoresist layer is less than one micrometer.

7. The method for manufacturing a roller mold according to claim 1, further including performing a baking step on the photoresist layer between the step of removing the mold and the UV light exposure step.

8. The method for manufacturing a roller mold according to claim 1, wherein the UV light exposure step includes using a deep ultraviolet light.

9. The method for manufacturing a roller mold according to claim 1, wherein the step of forming the structure layer is performed by an electron beam evaporation method, a thermal evaporation method, a chemical vapor deposition method or a physical vapor deposition method.

10. The method for manufacturing a roller mold according to claim 1, wherein the step of removing the photoresist layer, and the structure layer and the transferred pattern layer on the photoresist layer is performed by a lift-off method.

11. The method for manufacturing a roller mold according to claim 1, wherein the transferred pattern layer includes pattern features on the sub-micrometer scale.

12. The method for manufacturing a roller mold according to claim 1, wherein the transferred pattern layer includes pattern features on the nanometer scale.

13. The method for manufacturing a roller mold according to claim 1, wherein the mold is a rigid mold.

14. The method for manufacturing a roller mold according to claim 13, wherein a material of the mold is silicon, quartz, glass or metal.

15. The method for manufacturing a roller mold according to claim 1, wherein the mold is a flexible mold.

16. The method for manufacturing a roller mold according to claim 15, wherein the mold is composed of a flexible material having an anti-stick property, and the flexible material of the mold is ethylene tetrafluoroethylene produced by the DuPont Company.

17. The method for manufacturing a roller mold according to claim 1, wherein the convex portion and the concave portion are further covered with an anti-stick layer before the transferred pattern layer is formed.

18. A method for manufacturing a roller mold, including:
providing a body, wherein the body is a cylinder;
forming a photoresist layer completely covering a cambered surface of the body;
providing a mold, wherein a surface of the mold includes a pattern structure including a convex portion and a concave portion, and the convex portion and the concave portion are covered with a transferred pattern layer;
pressing the surface of the mold on the photoresist layer;
rolling the body to transfer the transferred pattern layer on the convex portion onto the photoresist layer;
removing the mold;
performing an UV light exposure step on an exposed portion of the photoresist layer to transfer a pattern of the transferred pattern layer to the photoresist layer;
removing the exposed portion of the photoresist layer to expose a portion of the cambered surface of the body;
performing an etching step on the portion of the cambered surface to remove a portion of the body to form a plurality of concave portions in the cambered surface; and
removing the photoresist layer and the transferred pattern layer.

19. The method for manufacturing a roller mold according to claim 18, wherein a material of the body is glass, quartz, or metal.

20. The method for manufacturing a roller mold according to claim 18, wherein the step of forming the photoresist layer is performed by a spray method.

21. The method for manufacturing a roller mold according to claim 18, wherein the step of forming the photoresist layer is performed by an immersion method.

22. The method for manufacturing a roller mold according to claim 18, wherein the photoresist layer is composed of a positive-tone photoresist or a negative-tone photoresist.

23. The method for manufacturing a roller mold according to claim 18, wherein a thickness of the photoresist layer is less than one micrometer.

24. The method for manufacturing a roller mold according to claim 18, further including performing a baking step on the photoresist layer between the step of removing the mold and the UV light exposure step.

25. The method for manufacturing a roller mold according to claim 18, wherein the UV light exposure step includes using a deep ultraviolet light.

26. The method for manufacturing a roller mold according to claim 18, wherein the etching step is a wet etching step.

27. The method for manufacturing a roller mold according to claim 18, wherein the step of removing the photoresist layer and the transferred pattern layer is performed by a lift-off method.

28. The method for manufacturing a roller mold according to claim 18, wherein the transferred pattern layer includes pattern features on the sub-micrometer scale.

29. The method for manufacturing a roller mold according to claim 18, wherein the transferred pattern layer includes pattern features on the nanometer scale.

30. The method for manufacturing a roller mold according to claim 18, wherein the mold is a rigid mold.

31. The method for manufacturing a roller mold according to claim 30, wherein a material of the mold is silicon, quartz, glass or metal.

32. The method for manufacturing a roller mold according to claim 18, wherein the mold is a flexible mold.

33. The method for manufacturing a roller mold according to claim 32, wherein the mold is composed of a flexible material having an anti-stick property, and the flexible material of the mold is ethylene tetrafluoroethylene produced by the DuPont Company.

34. The method for manufacturing a roller mold according to claim 18, wherein the convex portion and the concave portion are further covered with an anti-stick layer before the transferred pattern layer is formed.
